(19) United States
(12) Patent Application Publication
(10) Pub. No.: US 2025/0260174 A1
(43) Pub. Date: Aug. 14, 2025

(54) PLANER ANTENNA

(71) Applicants: ADVANTEST CORPORATION, Tokyo (JP); The University of Tokyo, Tokyo (JP)

(72) Inventors: Koji ASAMI, Saitama (JP); Tetsuya IIZUKA, Tokyo (JP); Nguyen Ngoc MAI-KHANH, Tokyo (JP); Akio HIGO, Tokyo (JP); Zolboo BYAMBADORJ, Tokyo (JP)

(21) Appl. No.: 19/193,850

(22) Filed: Apr. 29, 2025

Related U.S. Application Data
(63) Continuation of application No. PCT/JP2023/007439, filed on Feb. 28, 2023.
(60) Provisional application No. 63/432,705, filed on Dec. 15, 2022.

(51) Int. Cl. H01Q 21/00; H01Q 21/06

(52) U.S. Cl. CPC H01Q 21/0031; H01Q 21/067

(57) ABSTRACT

An antenna array with multiple testing antenna elements 14 that can test a device-under-test 12 in a practical way, thus allowing for a multitude of efficiencies (e.g. time saving, less errors, less mechanical components, etc.). At least a portion of each of the planer antenna elements 14 of an antenna array may be formed between an upper ground plane 16 and a lower ground plane 18, which may enhance electromagnetic characteristics. In other configurations, defective ground structures {22, 23} may be formed in the upper ground plane 16 and/or a lower ground plane 18, which may enhance electromagnetic characteristics. In some configurations, the defective ground structure {22, 23} may be formed above a pole portion 14P of at least one planer antenna element 14. In other configurations, the defective ground structure {22, 23} is formed between the pole portions 14P of two adjacent planer antenna elements 14.

### CROSS-REFERENCE TO RELATED APPLICATION

This application is a continuation of International Application No. PCT/JP2023/007439 filed on Feb. 28, 2023, which claims priority to U.S. Application No. 63/432,705 filed on Dec. 15, 2022, the contents of which are hereby incorporated by reference in their entirety.

### 1. TECHNICAL FIELD

The present invention relates to a planer antenna.

### 2. RELATED ART

Consumer and industrial products that include electronic devices, inherently all emit some level of electromagnetic energy. This electromagnetic energy may be in the form of radio waves that are electromagnetic noise. Depending on the application of an electronic device, a certain level of electromagnetic noise may be tolerated. However, in some applications of electronic devices, electromagnetic noise above a certain amount may generate undesirable electromagnetic interference (EMI). Electromagnetic interference (EMI) can be undesirable because the EMI can compromise the operation of nearby electronic devices. Electromagnetic interference (EMI) can be undesirable because there are legal limits or industrial requirements to the amount of EMI that an electronic device can emit.

Prior to the completion of the manufacturing process, an electronic device may need to be tested in order to determine if the electronic device complies with all electromagnetic interference (EMI) requirements. During the testing of an electronic device, the electronic device can be referred to as a device-under-test. Some of these electromagnetic energy emissions are near-field (NF) electromagnetic interference (EMI) characteristics, such that the attributes of the device-under-test should be tested over the entire surface of the device-under-test. It may be unnecessarily time consuming or otherwise impractical for a testing device to include only one testing antenna element for near-field (NF) scanning or facilitating electromagnetic interference (EMI) analysis of the device-under-test, because a testing device with only a single testing antenna element must be moved over the surface of the device-under-test to take multiple readings during the testing process.

### GENERAL DISCLOSURE

Some embodiments relate to an antenna array with multiple testing antenna elements that can test a device-under-test in a practical way that does not require any movement of the testing device over the surface of the device-under-test to take multiple readings, thus allowing for a multitude of efficiencies (e.g. time saving, less errors, less mechanical components, etc.). In some embodiments, at least a portion of each of the planer antenna elements of an antenna are formed between a first ground plane and a second ground plane, which may enhance electromagnetic characteristics. In other embodiments, defective ground structures are formed in the first ground plane and/or a second ground plane, which may enhance electromagnetic characteristics. In some embodiments, the defective ground structure is formed above a pole portion of a planer antenna element. In other embodiments, the defective ground structure is formed between the pole portions of two adjacent planer antenna elements.

### BRIEF DESCRIPTION OF THE DRAWINGS

FIG. 1A illustrates a testing device including an antenna array and a device-under-test, in accordance with embodiments.

FIG. 1B illustrates a testing device including an antenna array and a device-under-test, in accordance with embodiments.

FIG. 2A illustrates a planer antenna element between a first ground plane and a second ground plane, in accordance with embodiments.

FIG. 2B illustrates a planer antenna element between a first ground plane and a second ground plane, in accordance with embodiments.

FIG. 2C illustrates a planer antenna element between a first ground plane and a second ground plane, in accordance with embodiments.

FIG. 3A illustrates a planer antenna element (without the substrate illustrated) between a first ground plane and a second ground plane, in accordance with embodiments.

FIG. 3B illustrates a planer antenna element (without the substrate illustrated) between a first ground plane and a second ground plane, in accordance with embodiments.

FIG. 3C illustrates a planer antenna element (without the substrate illustrated) between a first ground plane and a second ground plane, in accordance with embodiments.

FIG. 4A illustrates a planer antenna element with only one ground plane, in accordance with embodiments.

FIG. 4B illustrates a planer antenna element with only one ground plane, in accordance with embodiments.

FIG. 4C illustrates a planer antenna element with only one ground plane, in accordance with embodiments.

FIG. 5A illustrates a planer antenna element between a first ground plane and a second ground plane, in accordance with embodiments.

FIG. 5B illustrates a planer antenna element between a first ground plane and a second ground plane, in accordance with embodiments.

FIG. 5C illustrates a planer antenna element between a first ground plane and a second ground plane, in accordance with embodiments.

FIG. 6A illustrates a plurality of planer antenna elements in a one-dimensional array, in accordance with embodiments.

FIG. 6B illustrates a plurality of planer antenna elements in a one-dimensional array, in accordance with embodiments.

FIG. 6C illustrates a plurality of planer antenna elements in a one-dimensional array, in accordance with embodiments.

FIG. 7 illustrates a plurality of planer antenna elements in a two-dimensional array, in accordance with embodiments.

FIG. 8 illustrates a planer antenna element with a pointed tip, in accordance with embodiments.

FIG. 9 illustrates a planer antenna element with a curved shape, in accordance with embodiments.

FIG. 10 illustrates a planer antenna element with a rounded tip, in accordance with embodiments.

FIG. 11A illustrates a defective ground structure in a ground plane above one or more planer antenna elements, in accordance with embodiments.

FIG. 11B illustrates a defective ground structure in a ground plane above one or more planer antenna elements, in accordance with embodiments.

FIG. 12A illustrates a defective ground structure in a ground plane between two planer antenna elements, in accordance with embodiments.

FIG. 12B illustrates a defective ground structure in a ground plane between two planer antenna elements, in accordance with embodiments.

FIG. 12C illustrates a defective ground structure in a ground plane between two planer antenna elements, in accordance with embodiments.

FIG. 13A illustrates one or more defective ground structures in both an upper ground plane and a lower ground plane, in accordance with embodiments.

FIG. 13B illustrates one or more defective ground structures in both an upper ground plane and a lower ground plane, in accordance with embodiments.

FIG. 14A illustrates one or more defective ground structures in one of an upper ground plane or a lower ground plane, in accordance with embodiments.

FIG. 14B illustrates one or more defective ground structures in one of an upper ground plane or a lower ground plane, in accordance with embodiments.

### DESCRIPTION OF EXEMPLARY EMBODIMENTS

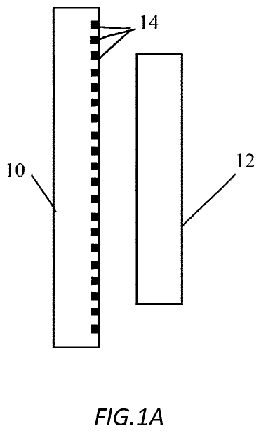

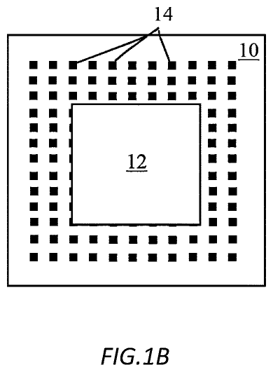

Example FIGS. 1A and 1B illustrate a testing device 10 including an antenna array 14 and a device-under-test 12, in accordance with embodiments. In embodiments, one or more planer antenna elements 14 are configured to detect electromagnetic propagation characteristics of a device-under-test 12.

Embodiments relate to an antenna array 14 with multiple testing antenna elements that can test a device-under-test 12 in a practical way that does not require any movement of the testing device 10 over the surface of the device-under-test 12 to take multiple readings, thus allowing for a multitude of efficiencies (e.g. time saving, less errors, less mechanical components, etc.).

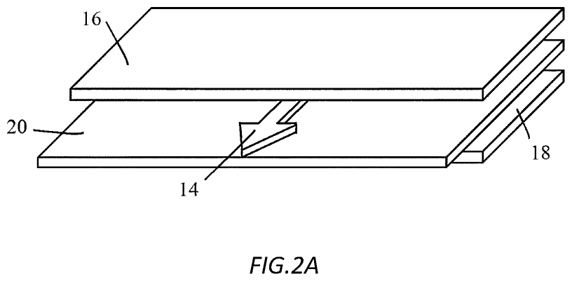

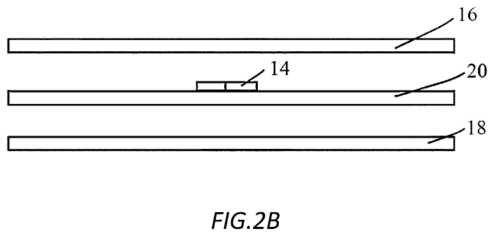

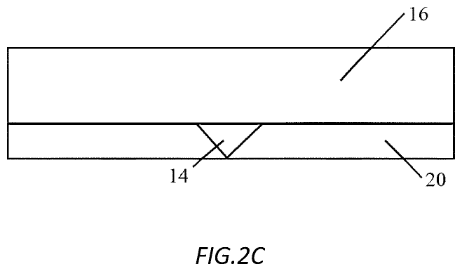

Example FIGS. 2A, 2B, and 2C illustrate a planer antenna element 14 between a first ground plane 16 and a second ground plane 18, in accordance with embodiments. FIG. 2A illustrates a perspective view, FIG. 2B illustrates a side view, and FIG. 2C illustrated a top view.

In embodiments, a testing device 10 may include one or more planer antenna elements 14, a first ground plane 16, and a second ground plane 18. For simplicity of explanation, FIGS. 2A, 2B, and 2C illustrate only one antenna element 14. In embodiments, at least a portion of the one or more antenna elements 14 are formed between the first ground plane 16 and the second ground plane 18. In embodiments, the first ground plane 16 and the second ground plane 18 are conducting surfaces configured to reflect radio waves emitted from the at least one planer antenna element 14. These reflections off of the first ground plane 16 and the second ground plane 18 may enhance the electromagnetic characteristics.

The one or more planer antenna elements 14 may be formed on a substrate 20, in accordance with embodiments. For example, substrate 20 may be a Megtron-6 substrate. Example characteristics of substrate 20 may be a dielectric constant of 3.2, loss tangent of 0.004, and thickness of 300 micrometers. One of ordinary skill in the art would appreciate suitable characteristics of substrate 20.

The one or more planer antenna element 14 is substantially insulated from the first ground plane 16 and the second ground plane 18, in accordance with embodiments. In embodiments, planer antenna element 14 is insulated and/or isolated from either first ground plane 16 or second ground plane 18 by air. In other embodiments, insulation and/or isolation may be provided by an insulating material instead of air formed by spacing apart planer antenna element 14, first ground plane, and second ground plane 16.

In embodiments, the at least one planer antenna element 14 is formed on a first plane, the first ground plane 16 is formed on a second plane, and the second ground plane 18 is formed on a third plane. The first plane, the second plane, and the third plane are all substantially parallel planes. In general, the first ground plane 16, second ground plane 18, and planer antenna element 14 should be substantially parallel to facilitate ideal electromagnetic characteristics. Those skilled in the art will appreciate that a certain level of tolerance may be acceptable in the parallel attributes without significantly affecting the electromagnetic characteristics.

In embodiments, the at least one planer antenna element 14 is at least one monopole antenna element. However, those skilled in the art may appreciate other types of antennas that may apply similar concepts as those described in the embodiments.

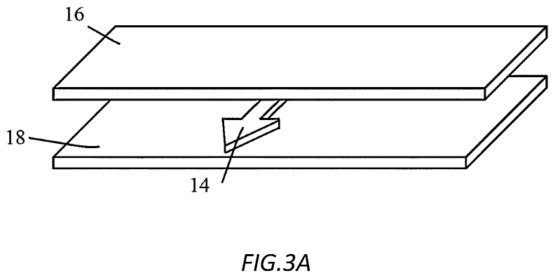

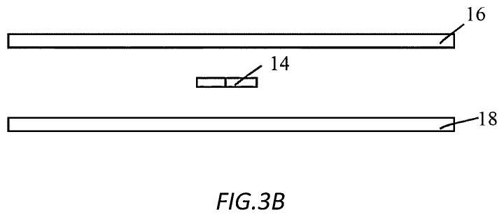

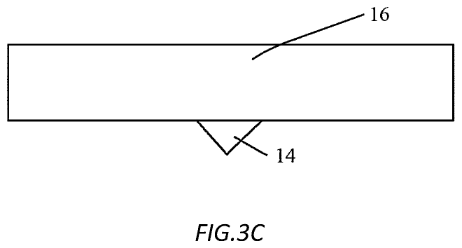

Example FIGS. 3A, 3B, and 3C illustrate a planer antenna element 14 (without the substrate illustrated) between a first ground plane 16 and a second ground plane 18, in accordance with embodiments. For the purposes of explanation, substrate 20 is not shown in FIGS. 3A, 3B, and 3C, because substrate 20 is generally a mechanical support structure for planer antenna element 14 and may not be directly related to the intended electromagnetic propagation characteristics. As illustrated in FIG. 3B, planer antenna element 14 is approximately halfway between first ground plane 16 and second ground plane 18. However, in embodiments, planer antenna element 14 may not be halfway between first ground plane 16 and second ground plane 18. As illustrated in FIG. 3C, a portion of planer antenna element extends beyond the boundaries of the first ground plane 16 and the second ground plane 18 in a direction perpendicular to the first ground plane 16 and the second ground plane 18, which affects the electromagnetic characteristics in an intentional manner.

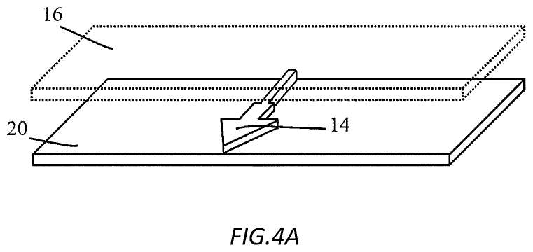

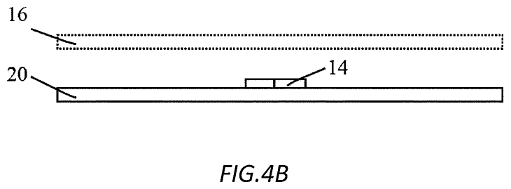

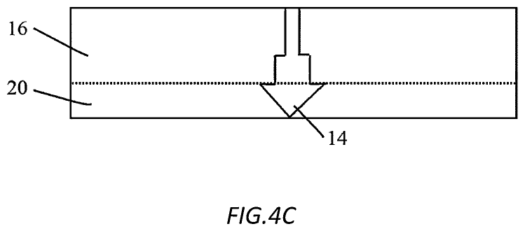

Example FIGS. 4A, 4B, and 4C illustrate a planer antenna element 14 with only one ground plane 16, in accordance with embodiments. In some embodiments, planer antenna element 14 has only one ground plane 16. All embodiments described herein may be modified to include only a single ground plane 16, as both a first ground plane 16 and a second ground plane 18 are not necessary in every embodiment. In other words, even if an embodiment describes both a first ground plane 16 and a second ground plane 18, there are other embodiments that include only a single ground plane 16, even if two ground planes are shown, illustrated, or described.

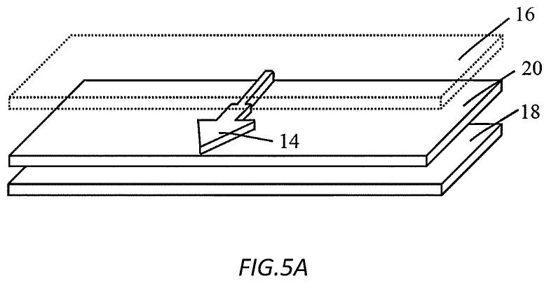

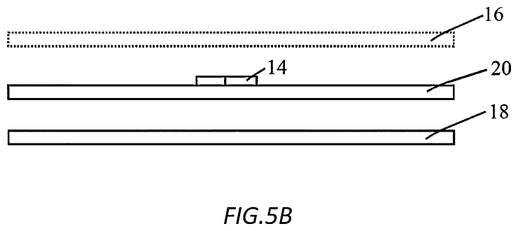

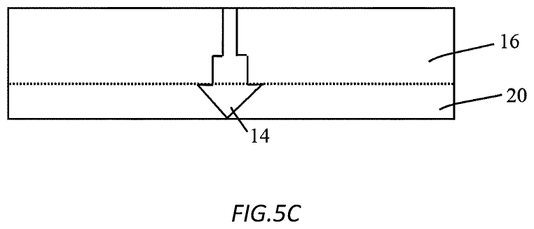

Example FIGS. 5A, 5B, and 5C illustrate a planer antenna element 14 between a first ground plane and a second ground plane, in accordance with embodiments. Example FIGS. 5A, 5B, and 5C are similar to example FIGS. 2A, 2B, and 2C, except that first ground plane 16 is shown as being transparent (dotted lines), so that planer antenna element 14 can be viewed without obstruction by first ground plane 16.

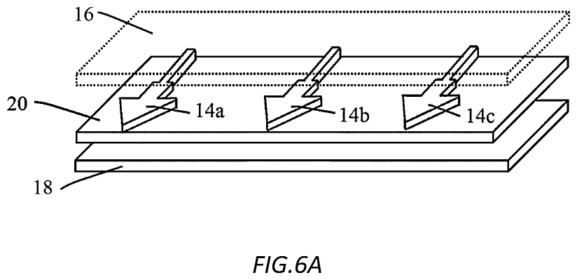

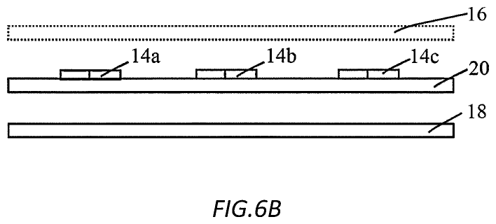

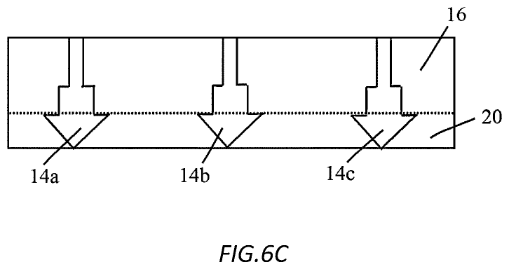

Example FIGS. 6A, 6B, and 6C illustrate a plurality of planer antenna elements {14a, 14b, 14c} in a one-dimensional array, in accordance with embodiments. The one or more planer antenna elements 14 include a plurality of planer antenna elements {14a, 14b, 14c}. The plurality of planer antenna elements {14a, 14b, 14c} are formed in an array.

The array of planer antenna elements {14a, 14b, 14c} is a one-dimensional array of planer antenna elements {14a, 14b, 14c} which share substrate 20. In embodiments, planer antenna elements {14a, 14b, 14c} are spaced substantially evenly apart from each other. However, in other embodiments, planer antenna elements {14a, 14b, 14c} may be spaced irregularly for either testing or electromagnetic characteristic purposes that are appreciated by those skilled in the art. Although only three planer antenna elements {14a, 14b, 14c} are illustrated, any number of planer antenna elements 14 may be disposed in a one-dimensional array.

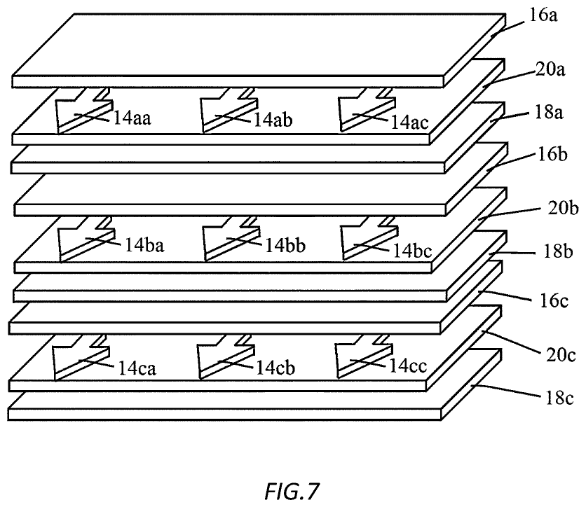

Example FIG. 7 illustrates plurality of planer antenna elements {14aa, 14ab, 14ac, 14ba, 14bb, 14bc, 14ca, 14cb, 14cc} in a two-dimensional array, in accordance with embodiments. The array of planer antenna elements {14aa, 14ab, 14ac, 14ba, 14bb, 14bc, 14ca, 14cb, 14cc} is a two-dimensional array of planer antenna elements 14.

Embodiments relate to a first one-dimensional array of planer antenna elements including the plurality of planer antenna elements {14aa, 14ab, 14ac}. Embodiments relate to a second one-dimensional array of planer antenna elements {14ba, 14bb, 14bc} associated with a third ground plane 16b and a fourth ground plane 18b. Embodiments relate to a third one-dimensional array of planer antenna elements {14ca, 14cb, 14cc} associated with a fifth ground plane 16c and a sixth ground plane 18c. Embodiments relate to a two-dimensional array of planer antenna elements including at least the first one dimensional array of planer antenna elements {14aa, 14ab, 14ac} and the second one-dimensional array of planer antenna elements {14ba, 14bb, 14bc}. In embodiments, any number of one-dimensional arrays of planer antenna elements may be used to form a two-dimensional array of planer antenna elements. The different one-dimensional arrays may be positioned apart from each other so that the tips of the planer antenna elements {14aa, 14ab, 14ac, 14ba, 14bb, 14bc, 14ca, 14cb, 14cc} have a uniform matrix spacing or an irregular spacing.

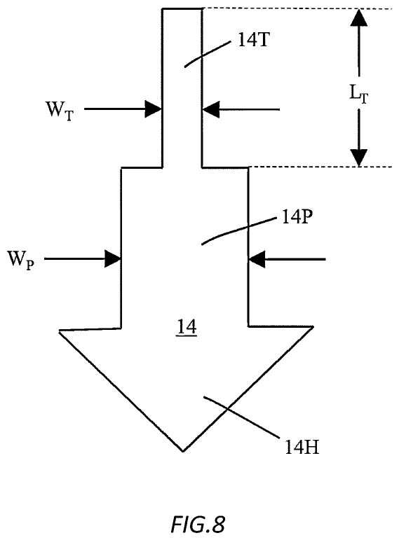

Example FIG. 8 illustrates a planer antenna element 14 with a pointed tip, in accordance with embodiments. In embodiments, each of the one or more planer antenna elements 14 includes a head portion 14H and a pole portion 14P contiguous with the head portion 14H. In embodiments, the pole portion 14P is in an area between the first ground plane 16 and the second ground plane 18. In embodiments, the head portion 14H is in an area that extends beyond a boundary of the first ground plane 16 and the second ground plane 18. Also see FIGS. 2C, 3C, 4C, 5C, and 6C, in accordance with embodiments. In embodiments, each of the at least one antenna element 14 includes a tail portion 14T contiguous with the pole portion 14P. The pole portion 14P is between the tail portion 14T and the head portion 14H.

In embodiments, a width W_{T} of the tail portion 14T is smaller than a width W_{P} of the pole portion 14P. In embodiments, the width W_{T} of the tail portion 14T is approximately 500 micrometers. In embodiments, a length L_{T} of the tail portion 14T is between approximately 6,800 micrometers and 9,500 micrometers. In embodiments, the length L_{T} of the tail portion 14T is between approximately 8,900 micrometers and 9,100 micrometers.

In embodiments, a width W_{H} of the head portion 14H varies based on a distance from the pole portion 14P. The width W_{H} of the head portion 14H has a maximum width at a point closest to the pole portion 14P. The width W_{H} of the head portion 14H has a minimum width at a point furthest away from the pole portion 14P.

Those skilled in the art appreciate other dimensions of planer antenna element 14 depending on the application and/or intended electromagnetic characteristics.

In embodiments, the head portion 14H has an arrow shape, as illustrated in FIG. 8. However, those skilled in the art appreciate that other shapes of the head portion 14H may be implemented, in accordance with the embodiments.

In embodiments, head portion 14H has a pointed tip. However, those skilled in the art appreciate that other shapes of the head portion 14H may be implemented without a pointed tip. In some embodiments, a non-pointed tip may be implemented for intended electromagnetic characteristics. In other embodiments, a non-pointed tip may be implemented to facilitate practical and/or efficient manufacturing techniques of the planer antenna element 14.

In embodiments, the point of the head portion 14H furthest away from the tail portion 14T is a tip. In embodiments, illustrated in FIG. 8, the head portion 14H has a substantially straight profile. However, in other embodiments, other profiles may be implemented, as appreciated by those skilled in the art.

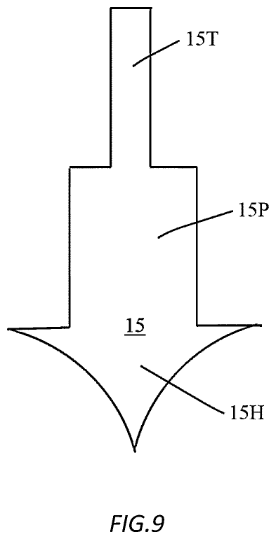

Example FIG. 9 illustrates a planer antenna element 15 with a curved shape, in accordance with embodiments. In embodiments, the head portion 15H has a curved profile for either electromagnetic propagation reasons or practical manufacturing reasons. In embodiments, the head portion 15H has a substantially parabolic profile. In embodiments, the head portion 15H has a substantially exponential varied profile. Embodiments relate to any profile of the head portion 15H of planer antenna element 15, as appreciated by those skilled in the art.

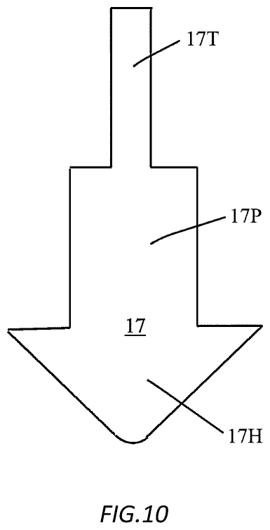

Example FIG. 10 illustrates a planer antenna element 17 with a rounded tip, in accordance with embodiments. As discussed above, embodiments where the head portion 17H has a rounded tip may be because of intended electromagnetic characteristics and/or practical manufacturing technique reasons.

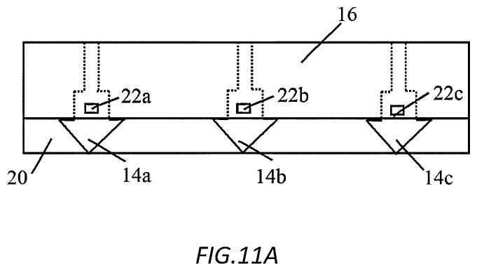

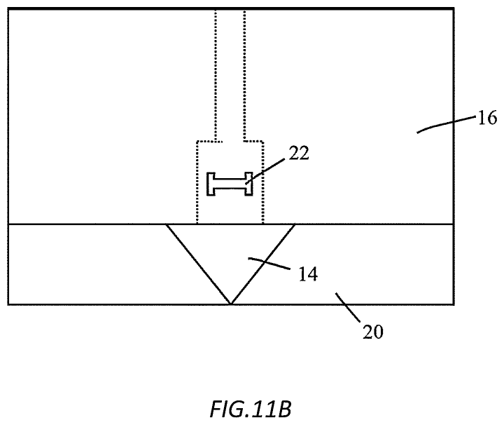

Example FIGS. 11A and 11B illustrate a defective ground structure {22a, 22b, 22c} in a ground plane above one or more planer antenna elements {14a, 14b, 14c}, in accordance with embodiments. In embodiments, the defective ground structure {22a, 22b, 22c} is configured to minimize a return loss of the first planer antenna element {14a, 14b, 14c}.

In embodiments, the defective ground structure {22a, 22b, 22c} is at least one slot in at least one of the first ground plane 16 or the second ground plane 18. In other words, in embodiments, the defective ground structure {22a, 22b, 22c} is the removal or prevention of formation of a portion of the first ground plane 16 during a manufacturing process.

In embodiments, the at least one planer antenna element {14a, 14b, 14c} includes a first planer antenna element 14 and the defective ground structure 22 that overlaps the pole portion 14P of the first planer antenna element 14 in a direction perpendicular to at least one of the first ground plane 16 or the second ground plane 18. Although planer antenna element 14 is illustrated as an example, other embodiments can implement other shapes (e.g. planer antenna element 15, planer antenna element 17, etc.).

In embodiments, the at least one slot of the defective ground structure 22 is a single slot. However, in other embodiments, the defective ground structure 22 may be multiple slots.

In embodiments, the at least one slot of the defective ground structure 22 has an I-shape. However, in other embodiments, the defective ground structure 22 may have another shape appreciated by those skilled in the art. In embodiments, the longest dimension of the I-shape is parallel to a boundary between the head portion 14H and the pole portion 14P and a shortest dimension of the I-shape is perpendicular to the boundary between the head portion 14H and the pole portion 14P.

In embodiments, there is only ground plane 16 and ground plane 18 is non-existent. In embodiments, an apparatus includes at least one planer antenna element {14a, 14b, 14c} and a single ground plane 16. The single ground plane 16 has a defective ground structure {22a, 22b, 22c}. The defective ground structure {22a, 22b, 22c} is at least one slot in the single ground plane 16. In embodiments, the at least one planer antenna element {14a, 14b, 14c} includes a first planer antenna element 14 and the defective ground structure overlaps 22 the pole portion 14P of the first planer antenna element 14 in a direction perpendicular to the single ground plane 16.

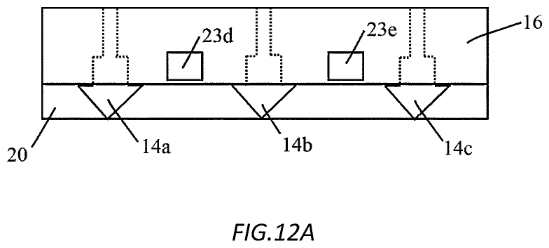

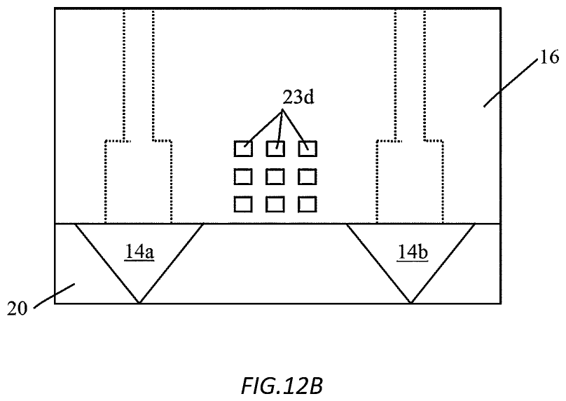

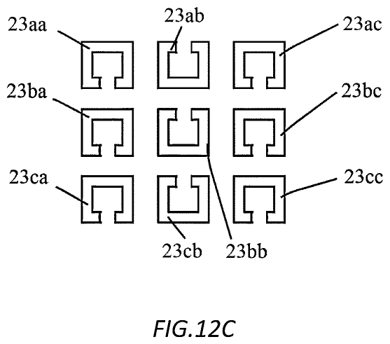

Example FIGS. 12A, 12B, and 12C illustrate a defective ground structure {23d, 23e} {23aa, 23ab, 23ac, 23ba, 23bb, 23bc, 23ca, 23cb, 23cc} in a ground plane 16 between two planer antenna elements {14a, 14b} or {14b, 14c}, in accordance with embodiments. In embodiments, the defective ground structure {23d, 23e} {23aa, 23ab, 23ac, 23ba, 23bb, 23bc, 23ca, 23cb, 23cc} is configured to minimize a return loss of the first planer antenna element {14a, 14b, 14c}. In embodiments, the defective ground structure {23d, 23e} {23aa, 23ab, 23ac, 23ba, 23bb, 23bc, 23ca, 23cb, 23cc} is configured to minimize coupling between the first planer antenna element 14a and the second planer antenna element 14b or between the second planer antenna element 24b and the third planer antenna element 24c.

In embodiments, the defective ground structure {23d, 23e} or {23aa, 23ab, 23ac, 23ba, 23bb, 23bc, 23ca, 23cb, 23cc} is at least one slot in at least one of the first ground plane 16 or the second ground plane 18. In some embodiments, the defective ground structure {23d, 23e} or {23aa, 23ab, 23ac, 23ba, 23bb, 23bc, 23ca, 23cb, 23cc} is at least one slot in only one of the first ground plane 16 or the second ground plane 18.

In embodiments, the defective ground structure {23d, 23e} or {23aa, 23ab, 23ac, 23ba, 23bb, 23bc, 23ca, 23cb, 23cc} is in an area of at least one of the first ground plane 16 or the second ground plane 18 that does not overlap the pole portion {14p, 15p, 17p} in a direction perpendicular to at least one of the first ground plane 16 or the second ground plane 18.

In embodiments, there is only ground plane 16 and ground plane 18 is non-existent. In other words, some embodiments include two ground planes and some embodiments include only a single ground plane.

In embodiments, the at least one planer antenna element 14 includes a first planer antenna element 14a adjacent to a second planer antenna element 14b. The first planer antenna element 14a and the second planer antenna element 14b both at least partially overlap at least one of the first ground plane 16 or the second ground plane 18 in the direction perpendicular to at least one of the first ground plane 16 or the second ground plane 18. The defective ground structure 23d is between the first planer antenna element 14a and the second planer antenna element 14b. The defective ground structure 23d does not overlap either the first planer antenna element 14a or the second planer antenna element 14b in the direction perpendicular to at least one of the first ground plane or the second ground plane. Likewise, in embodiments, defective ground structure 23e is between second planer antenna element 14b and third planer antenna element 14c.

In embodiments, the at least one slot {23aa, 23ab, 23ac, 23ba, 23bb, 23bc, 23ca, 23cb, 23cc} is a matrix of slots. In embodiments, each slot of the matrix of slots {23aa, 23ab, 23ac, 23ba, 23bb, 23bc, 23ca, 23cb, 23cc} has a square shape with a gap on one edge of the square shape. In embodiments, an orientation of the gap on one edge of the square shape is different for at least two slots of the matrix of slots {23aa, 23ab, 23ac, 23ba, 23bb, 23bc, 23ca, 23cb, 23cc}.

In embodiments, the matrix of slots comprises a plurality of rows of slots {23aa, 23ab, 23ac, 23ba, 23bb, 23bc, 23ca, 23cb, 23cc}. Each of the plurality of rows of slots are parallel to both the first planer antenna element 14a and the second planer antenna element 14b. The orientation of the gap on one edge of the square shape of each slot {23aa, 23ab, 23ac} {23ba, 23bb, 23bc} {23ca, 23cb, 23cc} in a same row of slots is the same. The plurality of rows of slots comprises a first row of slots adjacent to a second row of slots. The orientation of the gap on one edge of the square shape of each slot in the first row of slots is different than the orientation of the gap on one edge of the square shape of each slot in the second row of slots. In other embodiments, there may be other patterns of variations in the orientations of the gaps, as appreciated by those skilled in the art.

In embodiments, the one edge of the square shape on which there is the gap is an edge that is perpendicular to both the first planer antenna element 14a and the second planer antenna element 14b. In embodiments, the matrix of slots may be at the edge of the boundary of the first ground plane 16, while in other embodiments the matrix of slots may be spaced away from the edge of the boundary of the first ground plane 16.

In embodiments, there is only ground plane 16 and ground plane 18 is non-existent. In embodiments, an apparatus may include at least one planer antenna element {14a, 14b, 14c} and a single ground plane 16. The single ground plane 16 may have a defective ground structure {23d, 23e} {23aa, 23ab, 23ac, 23ba, 23bb, 23bc, 23ca, 23cb, 23cc}. The defective ground structure {23d, 23e} {23aa, 23ab, 23ac, 23ba, 23bb, 23bc, 23ca, 23cb, 23cc} is at least one slot in the single ground plane 16. In embodiments, the at least one planer antenna element {14a, 14b, 14c} includes a first planer antenna element 14a adjacent to a second planer antenna element 14b. The first planer antenna element 14a and the second planer antenna element 14b both at least partially overlap the ground plane in the direction perpendicular to the ground plane. The defective ground structure {23d, 23e} {23aa, 23ab, 23ac, 23ba, 23bb, 23bc, 23ca, 23cb, 23cc} is between the first planer antenna element and the second planer antenna element. The defective ground structure {23d, 23e} {23aa, 23ab, 23ac, 23ba, 23bb, 23bc, 23ca, 23cb, 23cc} does not overlap either the first planer antenna element 14a or the second planer antenna element 14b in the direction perpendicular to the ground plane.

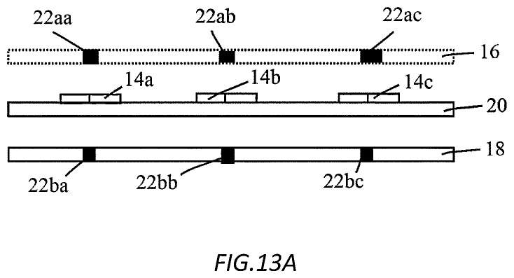

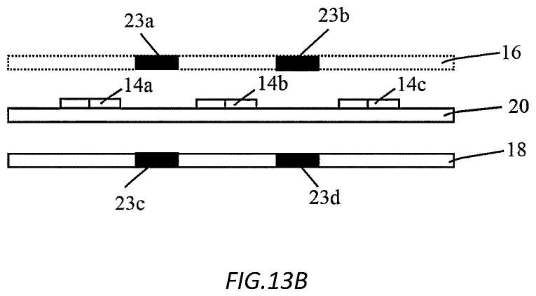

Example FIGS. 13A and 13B illustrate one or more defective ground structures {22aa, 22ab, 22ac, 22ba, 22bb, 22bc} or {22a, 22b, 22c, 22d, 22d} in both an upper ground plane 16 and a lower ground plane 18, in accordance with embodiments. In embodiments, the defective ground structure {22aa, 22ab, 22ac, 22ba, 22bb, 22bc} or {22a, 22b, 22c, 22d, 22d} is at least one slot in at least one of the first ground plane 16 or the second ground plane 18.

In embodiments, as illustrated in FIG. 13A, at least one of the first ground plane 16 or the second ground plane 18 has a defective ground structure {22aa, 22ab, 22ac, 22ba, 22bb, 22bc} or {22a, 22b, 22c, 22d, 22d}. In embodiments, as illustrated in FIG. 13B, the defective ground structure {22aa, 22ab, 22ac, 22ba, 22bb, 22bc} or {22a, 22b, 22c, 22d, 22d} is in both the first ground plane 16 and the second ground plane 18.

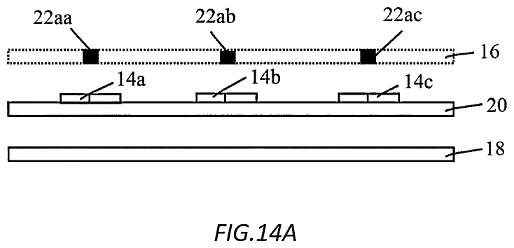

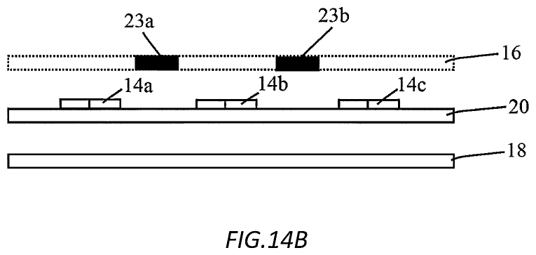

Example FIGS. 14A and 14B illustrate one or more defective ground structures {22aa, 22ab, 22ac} or {22a, 22b} in only one of an upper ground plane 16 or a lower ground plane 18, in accordance with embodiments.

In embodiments, the defective ground structure {22aa, 22ab, 22ac} or {22a, 22b} is at least one slot in at least one of the first ground plane 16 or the second ground plane 18. Although FIGS. 14A and 14B illustrate defective ground structures {22aa, 22ab, 22ac} or {22a, 22b} in only first ground plane 16 with no defective ground structures in the second ground plane 18, embodiments relate to defective ground structure in second ground plane 18 and no defective ground structure in the first ground plane 16.

It will be obvious and apparent to those skilled in the art that various modifications and variations can be made in the embodiments disclosed. This, it is intended that the disclosed embodiments cover the obvious and apparent modifications and variations, provided that they are within the scope of the appended claims and their equivalents.

What is claimed is:

1. An apparatus comprising:
at least one planer antenna element;
a first ground plane; and
a second ground plane,
wherein at least a portion of the at least one planer antenna element is formed between the first ground plane and the second ground plane.

2. The apparatus of claim 1, wherein:
the at least one planer antenna element comprises a plurality of planer antenna elements; and
the plurality of planer antenna elements are formed in an array.

3. The apparatus of claim 1, wherein the at least one planer antenna element is configured to detect electromagnetic characteristics of a device-under-test.

4. The apparatus of claim 1, wherein the at least one planer antenna element is at least partially insulated from the first ground plane and the second ground plane.

5. The apparatus of claim 2, wherein the array of planer antenna elements is a one-dimensional array of planer antenna elements.

6. The apparatus of claim 2, wherein the array of planer antenna elements is a two-dimensional array of planer antenna elements.

7. The apparatus of claim 2, comprising:
a first one-dimensional array of planer antenna elements comprising the plurality of planer antenna elements;
a second one-dimensional array of planer antenna elements associated with a third ground plane and a fourth ground plane; and
a two-dimensional array of planer antenna elements comprising the first one dimensional array of planer antenna elements and the second one-dimensional array of planer antenna elements.

8. The apparatus of claim 1, wherein
the at least one planer antenna element is formed on a first plane;
the first ground plane is formed on a second plane; and
the second ground plane is formed on a third plane;
wherein the first plane, the second plane, and the third plane are all substantially parallel planes.

9. The apparatus of claim 1, wherein the at least one planer antenna element is at least one monopole antenna element.

10. The apparatus of claim 1, wherein the first ground plane and the second ground plane are conducting surfaces configured to reflect radio waves emitted from the at least one planer antenna element.

11. The apparatus of claim 1, wherein each of the at least one antenna element comprises:
a head portion; and
a pole portion contiguous with the head portion.

12. The apparatus of claim 11, wherein:
the pole portion is in an area between the first ground plane and the second ground plane; and
the head portion is in an area that extends beyond a boundary of the first ground plane and the second ground plane.

13. The apparatus of claim 11, wherein at least one of the first ground plane or the second ground plane has a defective ground structure.

14. The apparatus of claim 13, wherein the defective ground structure is configured to minimize a return loss of the first planer antenna element.

15. The apparatus of claim 13, wherein the defective ground structure is at least one slot in at least one of the first ground plane or the second ground plane.

16. The apparatus of claim 15, wherein:
the at least one planer antenna element comprises a first planer antenna element; and
the defective ground structure overlaps the pole portion of the first planer antenna element in a direction perpendicular to at least one of the first ground plane or the second ground plane.

17. The apparatus of claim 16, wherein the at least one slot of the defective ground structure has an I-shape.

18. The apparatus of claim 17, wherein the at least one slot is a single slot.

19. The apparatus of claim 17, wherein:
a longest dimension of the I-shape is parallel to a boundary between the head portion and the pole portion; and
a shortest dimension of the I-shape is perpendicular to the boundary between the head portion and the pole portion.

20. The apparatus of claim 15, wherein the defective ground structure is in an area of at least one of the first ground plane or the second ground plane that does not overlap the pole portion in a direction perpendicular to at least one of the first ground plane or the second ground plane.

21. The apparatus of claim 20, wherein:
the at least one planer antenna element comprises a first planer antenna element adjacent to a second planer antenna element;
the first planer antenna element and the second planer antenna element both at least partially overlap at least one of the first ground plane or the second ground plane in the direction perpendicular to at least one of the first ground plane or the second ground plane;
the defective ground structure is between the first planer antenna element and the second planer antenna element; and
the defective ground structure does not overlap either the first planer antenna element or the second planer antenna element in the direction perpendicular to at least one of the first ground plane or the second ground plane.

22. The apparatus of claim 21, wherein the defective ground structure is configured to minimize coupling between the first planer antenna element and the second planer antenna element.

23. The apparatus of claim 21, wherein the at least one slot comprises a matrix of slots.

24. The apparatus of claim 23, wherein each slot of the matrix of slots has a square shape with a gap on one edge of the square shape.

25. The apparatus of claim 24, wherein an orientation of the gap on one edge of the square shape is different for at least two slots of the matrix of slots.

26. The apparatus of claim 25, wherein:
the matrix of slots comprises a plurality of rows of slots;
each of the plurality of rows of slots are parallel to both the first planer antenna element and the second planer antenna element;
the orientation of the gap on one edge of the square shape of each slot in a same row of slots is the same;
the plurality of rows of slots comprises a first row of slots adjacent to a second row of slots; and
the orientation of the gap on one edge of the square shape of each slot in the first row of slots is different than the orientation of the gap on one edge of the square shape of each slot in the second row of slots.

27. The apparatus of claim 24, wherein the one edge of the square shape on which there is the gap is an edge that is perpendicular to both the first planer antenna element and the second planer antenna element.

28. The apparatus of claim 13, wherein the defective ground structure is in both the first ground plane and the second ground plane.

29. The apparatus of claim 13, wherein the defective ground structure is in only one of the first ground plane or the second ground plane.

30. The apparatus of claim 11, wherein each of the at least one antenna element comprises:
a tail portion contiguous with the pole portion,
wherein the pole portion is between the tail portion and the head portion.

31. The apparatus of claim 30, wherein a width of the tail portion is smaller than a width of the pole portion.

32. The apparatus of claim 30, wherein the width of the tail portion is approximately 500 micrometers.

33. The apparatus of claim 30, wherein a length of the tail portion is between approximately 6,800 micrometers and 9,500 micrometers.

34. The apparatus of claim 33, wherein the length of the tail portion is between approximately 8,900 micrometers and 9,100 micrometers.

35. The apparatus of claim 11, wherein:
a width of the head portion varies based on a distance from the pole portion;
the width of the head portion has a maximum width at a point closest to the pole portion; and
the width of the head portion has a minimum width at a point furthest away from the pole portion.

36. The apparatus of claim 35, wherein the head portion has an arrow shape.

37. The apparatus of claim 35, wherein the head portion has at least one of:
a substantially straight profile;
a curved profile;
a substantially parabolic profile; and
an substantially exponential varied profile.

38. The apparatus of claim 35, wherein the point furthest away from the tail portion is a tip.

39. The apparatus of claim 38, wherein the tip is a rounded tip.

40. An apparatus comprising:
at least one planer antenna element; and
a ground plane,
wherein the ground plane has a defective ground structure, and
wherein the defective ground structure is at least one slot in the ground plane.

41. The apparatus of claim 40, wherein:
the at least one planer antenna element comprises a first planer antenna element; and
the defective ground structure overlaps the pole portion of the first planer antenna element in a direction perpendicular to the ground plane.

42. The apparatus of claim 40, wherein:
the at least one planer antenna element comprises a first planer antenna element adjacent to a second planer antenna element;
the first planer antenna element and the second planer antenna element both at least partially overlap the ground plane in the direction perpendicular to the ground plane;
the defective ground structure is between the first planer antenna element and the second planer antenna element; and
the defective ground structure does not overlap either the first planer antenna element or the second planer antenna element in the direction perpendicular to the ground plane.
